(19) United States
(12) Patent Application Publication
(10) Pub. No.: US 2006/0079046 A1
(43) Pub. Date: Apr. 13, 2006

(54) METHOD AND STRUCTURE FOR IMPROVING CMOS DEVICE RELIABILITY USING COMBINATIONS OF INSULATING MATERIALS

(75) Inventors: Haining Yang, Wappingers Falls, NY (US); Eng Hua Lim, Singapore (SG)

Correspondence Address: CANTOR COLBURN LLP - IBM FISHKILL, 55 GRIFFIN ROAD SOUTH, BLOOMFIELD, CT, 06002, US

(73) Assignee: INTERNATIONAL BUSINESS MACHINES CORPORATION, Armonk, NY (US)

(21) Appl. No.: 10/711,897

(22) Filed: Oct. 12, 2004

(51) Int. Cl. H01L 21/8238

(52) U.S. Cl. 438/199; 438/233; 438/981; 438/230

(57) ABSTRACT

A method for improving hot carrier effects in complementary metal oxide semiconductor (CMOS) devices includes forming a first configuration of insulating material over a first group of the CMOS devices, and forming a second configuration of insulating material over a second group of the CMOS devices. The first and said second configurations of insulating material are formed subsequent to a silicidation of the CMOS devices and prior to formation of a first interlevel (ILD) dielectric material over the CMOS devices.

### BACKGROUND

The present invention relates generally to semiconductor device processing techniques, and, more particularly, to a method and structure for improving CMOS device reliability using combinations of insulating materials.

Hot carrier effects in metal oxide semiconductor field effect transistor (MOSFET) devices are caused by high electric fields at the end of the channel, near the source/drain diffusion regions. More specifically, electrons that acquire great energy when passing through the high-field region can generate electron-hole pairs due to, for example, impact ionization, thus resulting in high gate leakage and early gate oxide breakdown by injecting hot carriers through the gate oxide to the gate material. As a further result, there is also a net negative charge density in the gate dielectric. The trapped charge accumulates with time, resulting in a positive threshold shift in the NMOS transistor, or a negative threshold shift in a PMOS transistor.

Since hot electrons are more mobile than hot holes, hot carrier effects cause a greater threshold skew in NMOS transistors than in PMOS transistors. Nonetheless, a PMOS transistor will still undergo negative threshold skew if its effective channel length (L_{eff}) is less than, for example, 0.8 microns (μm). Thin gate oxides by today's standards (e.g., less than 1.5 nanometers) tend to be less sensitive to hot carrier degradation, as the hot carrier can readily tunnel through a thin gate oxide. On the other hand, thicker gate oxide devices (e.g., more than 1.5 nanometers) are more vulnerable to hot carrier degradation, due to the fact that the hot carriers tend to accumulate in the oxide over time. Thus, for certain application specific integrated circuits such as input/output circuitry, there may be some devices on a single chip that are formed with thicker gate oxides with respect to other devices on the chip (e.g., logic or analog circuit transistors).

Existing approaches to reducing the effects of hot carrier degradation include the addition of impurities such as nitrogen, fluorine and chlorine to the gate oxide. However, the addition of impurities can be less effective for thicker gate oxides since the impurities (such as nitrogen) tend to be localized at the surface of the film. Moreover, the direct nitridation of a gate oxide can also be accompanied by unwanted effects, such as degradation of electron mobility.

Another technique that has been disclosed for improving device life due to hot carrier effects is the use of deuterium anneals. By substituting deuterium for hydrogen at the standard interface passivation anneal step, the lifetime of an NFET device can be improved by a factor of about 10-100. However, the deuterium anneal has to be performed at a sufficiently high temperature (e.g., over 500° C.) to be effective, which may cause dopant deactivation resulting in device degradation. Additional information regarding deuterium anneals may be found in the publication of Thomas G. Ference, et al., “The Combined Effects of Deuterium Anneals and Deuterated Barrier-Nitride Processing on Hot-Electron Degradation in MOSFET's,” IEEE Transactions on Electron Devices, Vol. 46, No. 4, April, 1999, pp. 747-753. Again, however, this technique is also generally applied to thinner gate oxides.

Accordingly, it would be desirable to be able to simultaneously improve hot carrier effects for devices such as NFETs and PFETs having relatively thick gate oxides.

### SUMMARY

The foregoing discussed drawbacks and deficiencies of the prior art are overcome or alleviated by a method for improving hot carrier effects in complementary metal oxide semiconductor (CMOS) devices. In an exemplary embodiment, the method includes forming a first configuration of insulating material over a first group of the CMOS devices, and forming a second configuration of insulating material over a second group of the CMOS devices. The first and said second configurations of insulating material are formed subsequent to a silicidation of the CMOS devices and prior to formation of a first interlevel (ILD) dielectric material over the CMOS devices.

In another embodiment, a structure for improving hot carrier effects in complementary metal oxide semiconductor (CMOS) devices includes a first configuration of insulating material formed over a first group of the CMOS devices, and a second configuration of insulating material formed over a second group of the CMOS devices. The first and said second configurations of insulating material are formed subsequent to a silicidation of the CMOS devices and prior to formation of a first interlevel (ILD) dielectric material over the CMOS devices.

### BRIEF DESCRIPTION OF THE DRAWINGS

Referring to the exemplary drawings wherein like elements are numbered alike in the several Figures:

FIG. 1 is a cross sectional view of a semiconductor substrate having a pair of complementary metal oxide semiconductor (CMOS) devices formed thereon, suitable for use in accordance with an embodiment of the invention;

FIGS. 2 through 8 illustrate an exemplary process flow for forming first and second configurations of insulating layers over silicided NFET and PFET devices, in accordance with a first embodiment of the invention;

FIG. 9 is an alternative embodiment of the structure of FIG. 8;

FIG. 10 is still another embodiment of the structure of FIG. 8;

FIG. 11 is still another embodiment of the structure of FIG. 8;

FIG. 12 is still another embodiment of the structure of FIG. 8;

FIG. 13 is a graph comparing hot carrier effects of conventionally fabricated, single nitride layer NFET structures with those configured with at least two different insulating layers; and

FIG. 14 is a graph comparing hot carrier effects of conventionally fabricated, single nitride layer PFET structures with those configured with at least two different insulating layers.

### DETAILED DESCRIPTION

Disclosed herein is a method and structure for improving CMOS device reliability using various combinations of insulating materials following silicidation of the gate electrode and source/drain diffusion regions. Briefly stated, a combination of different insulative layers is formed over a semiconductor wafer following the silicidation process, as opposed to, for example, a single nitride layer prior to the formation of the first interlevel dielectric layer. The different layers may be, in one embodiment, two types of nitride layers having different hydrogen concentrations and/or intrinsic stresses. Alternatively, the insulating layers may be combinations of nitride and oxide materials.

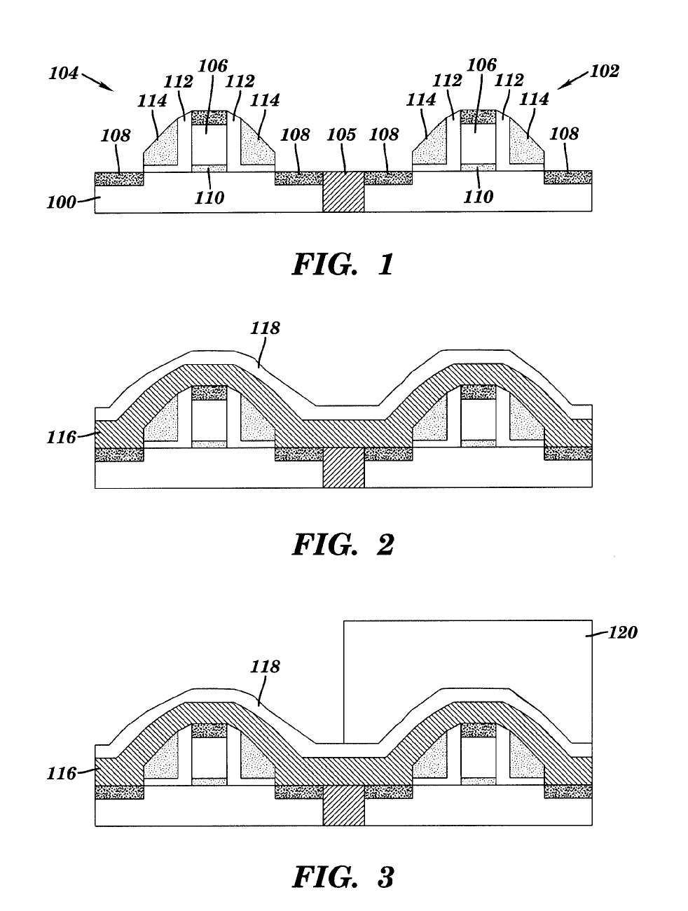

Referring initially to FIG. 1, there is shown a cross sectional view of a semiconductor substrate 100 having a pair of complementary metal oxide semiconductor (CMOS) devices (i.e., an NFET device 102 and a PFET device 104) formed thereon, and separated from one another by a shallow trench isolation 105. At the particular process stage of device manufacturing shown therein, the silicidation of the gate 106 material (e.g., polysilicon) and source/drain diffusion regions 108 has taken place, but prior to the formation of the first interlevel dielectric (ILD) layer (not shown). FIG. 1 further illustrates the gate oxide layers 110 (e.g., SiO₂) and nitride spacer layers 112, 114 used in the formation of the NFET 102 and PFET 104, as will be recognized by one skilled in the art.

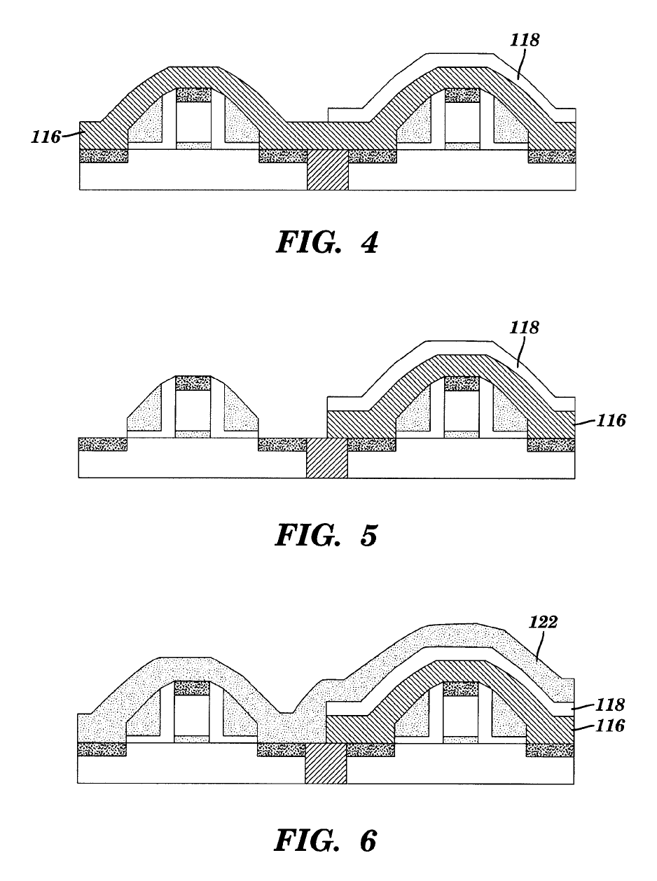

In accordance with a first embodiment, FIGS. 2 through 8 illustrate an exemplary process flow for forming first and second configurations of insulating layers over the silicided NFET 102 and PFET 104 devices. In FIG. 2, a first nitride layer 116 is formed over the entire structure, followed by an insulating hardmask layer 118, such as tetraethyl orthosilicate (TEOS). In the exemplary embodiment depicted, the first nitride layer is a tensile silicon nitride layer, such as Si₃N₄ deposited using a BTBAS (Bis(TertiaryButylAmino)Silane) precursor. Then, in FIG. 3, the TEOS hardmask layer 118 is patterned with a hardened photoresist layer 120 over the NFET device 102, and opened as shown in FIG. 4. In FIG. 5, the exposed first nitride layer 116 is etched from atop the PFET device 104, with the salicided gate and diffusion regions serving as an etch stop.

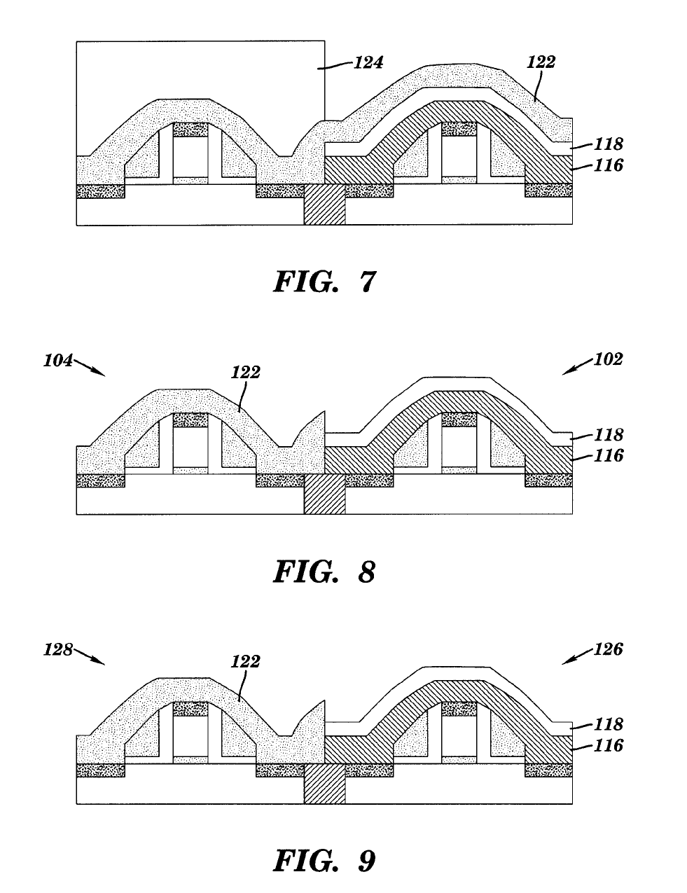

Proceeding to FIG. 6, a second nitride layer 122 is then formed over the entire structure. In the exemplary embodiment, the second nitride layer 122 is a compressive nitride layer, such as Si₃N₄ deposited by plasma enhanced chemical vapor deposition (PECVD) using a silane (SiH₂) precursor. As shown in FIG. 7, the second nitride layer 122 is then patterned using another resist layer 124, followed by an etch process so as to remove the second nitride layer 122 over the device portions having the first nitride layer 116 and TEOS hardmask layer 118. Thus, in FIG. 8, the NFET device 102 includes first nitride layer 116 and TEOS layer 118 over the salicided portions thereof, while the PFET device 104 includes the second nitride layer 122 over the salicided portions thereof. In this illustrative embodiment, layers 116 and 118 may be patterned to cover each of the NFET devices on the substrate, regardless of whether the gate oxides are “thick” or “thin,” while layer 122 may be patterned to cover each of the PFET devices on the substrate, regardless of the thicknesses of the gate oxides.

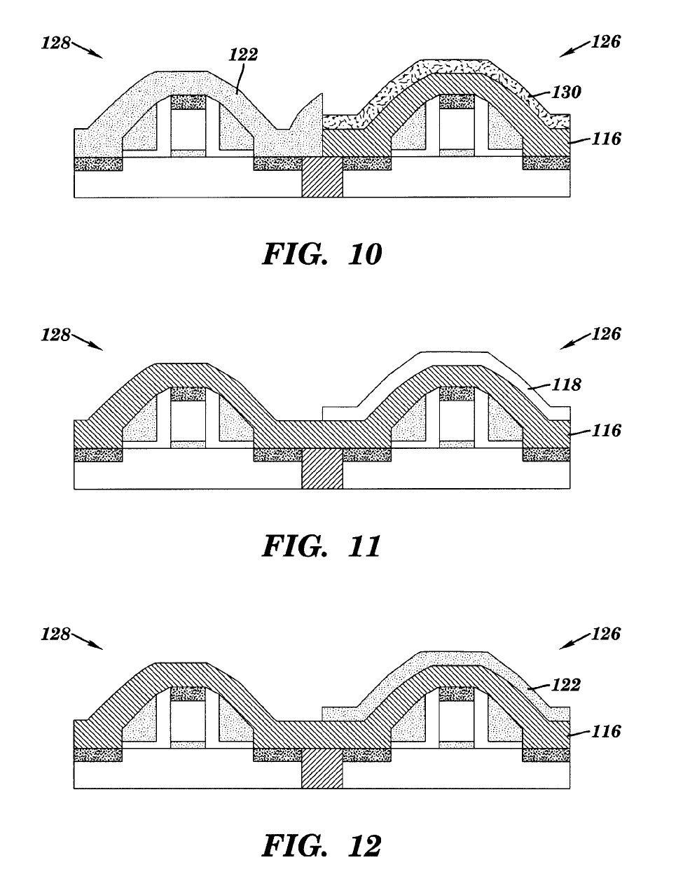

FIG. 9 is an alternative embodiment of FIG. 8, in which the first nitride layer 116 and TEOS layer 118 are patterned so as to be formed over thick gate oxide devices 126 (both NFET and PFET), while the second nitride layer 122 is patterned so as to be formed over thin gate oxide devices 128 (both NFET and PFET). In addition to the particular combination of insulating layers shown in FIGS. 8 and 9, other combinations of different insulating layers may be used with respect to thick and thin gate oxide devices. For example, as shown in FIG. 10, instead of an TEOS layer, the thick gate oxide device 126 has the first nitride layer 116 formed thereon, followed by a third nitride layer 130 (the thin gate oxide device still includes the second nitride layer 122 formed thereon). The third nitride layer 130 may be, for example a nitride deposited by plasma enhanced chemical vapor deposition (PECVD).

FIGS. 11 and 12 illustrate even further embodiments of insulating materials formed over the salicided CMOS devices. As shown in FIG. 11, the first nitride layer 116 is formed over all of the devices, regardless of whether they are NFET, PFET, thick or thin gate oxide devices. However, the thick gate oxide devices 126 are also provided with a second insulative layer, such as TEOS layer 118. Finally, the embodiment of FIG. 12 is similar to that of FIG. 11, in that the first nitride layer 116 covers each of the CMOS devices. Again, the thick gate oxide devices 126 are further provided with a second layer, in this case with the second nitride layer. It will thus be appreciated that several different combinations of insulative layering are possible, so long as there is a differentiation between the layer configuration formed on a first group of CMOS devices (e.g., NFETs, thick gate oxide devices) and the layer configuration formed on a second group of CMOS devices (e.g., PFETs, thin gate oxide devices). Stated another way, those devices for which hot carrier degradation is of particular concern, include at least a pair of different type insulating layers formed thereon, while the remaining devices include a single type of insulating layer formed thereon following silicidation and before interlevel dielectric formation.

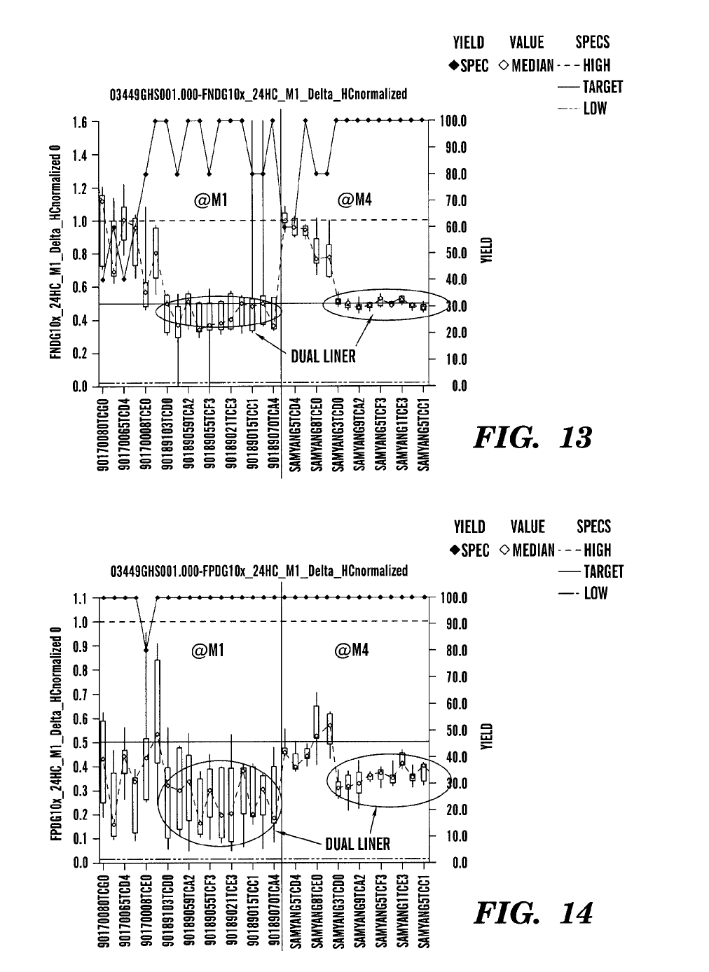

The advantages of the above described embodiments may be appreciated upon consideration of the test data presented in FIG. 13 and 14. In particular, FIG. 13 is a graph comparing hot carrier effects of conventionally fabricated NFET structures (i.e., a single Si₃N₄ layer over each salicided transistor) with those configured in accordance with the embodiment illustrated in FIG. 8 Normalized measurements of voltage threshold (Vₜ) shift were taken for a control group of wafer lots, as well as for a group of “dual insulating layer” wafers. The measurements were taken at both the M1 level of metallization (shown on the left side of the graph) and the M4 level (shown on the right side of the graph) in order to demonstrate the stability of the process. As can be seen, the conventionally formed wafer lots exhibited a higher normalized value of Vₜ shift, while the dual layer lots (shown circled in FIG. 13) have a uniformly lower value of Vₜ shift, thus indicating improved resistance to hot carrier degradation.

Finally, FIG. 14 is a graph comparing hot carrier effects of conventionally fabricated PFET structures (i.e., a single Si₃N₄ layer over each salicided transistor) with those configured in accordance with the dual layer approach of the present invention embodiments. Although, the improvements in Vₜ shift are not as dramatic for PFET devices, FIG. 14 nonetheless demonstrates an improvement in hot carrier effects when a dual insulating layer approach is implemented.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A method for improving hot carrier effects in complementary metal oxide semiconductor (CMOS) devices, the method comprising:
forming a first configuration of insulating material over a first group of the CMOS devices, said first group of the CMOS devices comprising NFET devices; and
forming a second configuration of insulating material over a second group of the CMOS devices, said second group of the CMOS devices comprises PFET devices;
wherein said first and said second configuration of insulating material are formed subsequent to a silicidation of the CMOS devices and prior to formation of a first interlevel (ILD) dielectric material over the CMOS devices; and
wherein said first configuration of insulating material comprises a tensile layer over said NFET devices and said second configuration of insulating material comprises a compressive layer over said PFET devices.

2. The method of claim 1, wherein said first configuration of insulating material further comprises at least a pair of individual insulating layers, and said second configuration of insulating material further comprises a single insulating layer.

3. (canceled)

4. The method of claim 2, wherein said first group of the CMOS devices comprises gate oxide thicknesses of a first range and said second group of the CMOS devices comprises gate oxide thicknesses of a second range.

5. The method of claim 2, wherein said pair of individual insulating layers further comprises a first nitride layer and an oxide layer, and said single insulating layer further comprises a second nitride layer.

6. The method of claim 5, wherein said first nitride layer is a tensile nitride layer, and said second nitride layer is a compressive nitride layer.

7. The method of claim 6, wherein said first nitride layer is Si₃N₄ deposited using a BTBAS (Bis(TertiaryButylAmino)Silane) precursor, said second nitride layer is Si₃N₄ deposited by plasma enhanced chemical vapor deposition (PECVD) using a silane (SiH₂) precursor, and said oxide layer is tetraethyl orthosilicate (TEOS).

8. The method of claim 2, wherein said pair of individual insulating layers further comprises a first nitride layer and a third nitride layer, and said single insulating layer further comprises a second nitride layer.

9. The method of claim 2, wherein said pair or individual insulating layers further comprises a first nitride layer and an oxide layer, and said single insulating layer further comprises said first nitride layer.

10. The method of claim 2, wherein said pair of individual insulating layers further comprises a first nitride layer and a second nitride layer, and said single insulating layer further comprises said first nitride layer.

11. The method of claim 1, wherein:
said first configuration of insulating material further comprises one of a single nitride layer and a single oxide layer; and
said second configuration of insulating material further comprises one of a single nitride layer, a single oxide layer, and a combination of a nitride and an oxide layer.

12. The method of claim 1, wherein said first configuration of insulating material comprises a compressive material and said second configuration of insulating material comprises a tensile material.

13. A structure for improving hot carrier effects in complementary metal oxide semiconductor (CMOS) devices, comprising:
a first configuration of insulating material formed over a first group of the CMOS devices; and
a second configuration of insulating material formed over a second group of the CMOS devices;
wherein said first and said second configurations of insulating material are formal subsequent to a silicidation of the CMOS devices and prior to formation of a first interlevel (ILD) dielectric material over the CMOS devices.

14. The structure of claim 13, wherein said first configuration further comprises at least a pair of individual insulating layers, and said second configuration of insulating devices further comprises a single insulating layer.

15. The structure of claim 14, wherein said first group of the CMOS devices comprises NFET devices and said second group of the CMOS devices comprises PFET devices.

16. The structure of claim 14, wherein said first group of the CMOS devices comprises gate oxide thicknesses of a first range and said second group of the CMOS devices comprises gate oxide thicknesses of a second range.

17. The structure of claim 14, wherein said pair of individual insulating layers further comprises a first nitride layer and an oxide layer, and said single insulating layer further comprises a second nitride layer.

18. The structure of claim 17, wherein said first nitride layer is a tensile nitride layer, and said second nitride layer is a compressive nitride layer.

19. The structure of claim 18, wherein said first nitride layer is Si₃N₄ deposited using a BTBAS (Bis(TertiaryButylAmino)Silane) precursor, said second nitride layer is Si₃N₄ deposited by plasma enhanced chemical vapor deposition (PECVD) using a silane (SiH₂) precursor, and said oxide layer is tetracthyl orthosilicate (TEOS).

20. The method of claim 14, wherein said pair of individual insulating layers further comprises a first nitride layer and a third nitride layer, and said single insulating layer further comprises a second nitride layer.

21. The structure of claim 14, wherein said pair of individual insulating layers further comprises a first nitride layer and an oxide layer, and said single insulating layer further comprises said first nitride layer.

22. The structure of claim 12, wherein said pair of individual insulating layers further comprises a first nitride layer and a second nitride layer, and said single insulating layer further comprises said first nitride layer.

23. The method of claim 13, wherein:
said first configuration or insulating material further comprises one of a single nitride layer and a single oxide layer; and
said second configuration of insulating material further comprises one of a single nitride layer, a single oxide layer, and a combination of a nitride and an oxide layer.

24. The method of claim 13, wherein said first configuration of insulating material comprises a compressive material and said second configuration of insulating material comprises a tensile material.
